(19) United States
(12) Patent Application Publication
(10) Pub. No.: US 2022/0098223 A1
(43) Pub. Date: Mar. 31, 2022

(54) HEXACOORDINATED ORGANOANTIMONY COMPLEX AND ORGANIC LIGHT-EMITTING DIODE USING THE SAME

(71) Applicants: Tokyo Metropolitan Public University Corporation, Tokyo (JP); FLASK Corporation, Yonezawa-shi (JP)

(72) Inventors: Soichi SATO, Tokyo (JP); Masato SAKABE, Tokyo (JP); Hisayuki KAWAMURA, Yonezawa-shi (JP)

(73) Assignees: Tokyo Metropolitan Public University Corporation, Tokyo (JP); FLASK Corporation, Yonezawa-shi (JP)

(21) Appl. No.: 17/480,202

(22) Filed: Sep. 21, 2021

(30) Foreign Application Priority Data
Sep. 25, 2020 (JP) 2020-160937

(51) Int. Cl. C07F 9/92; H01L 51/00

(52) U.S. Cl. CPC C07F 9/92; H01L 51/5016; H01L 51/0077

(57) ABSTRACT

Provided is a novel hexacoordinated organoantimony complex which emits blue light, and a blue light-emitting OLED comprising the same. The hexacoordinated organoantimony complex of the present invention has an intramolecular ligand so as to form an antimony-centered hexacoordinated structure, wherein carbons and antimony form one to three carbon-antimony bonds in the intramolecular ligand. The OLED of the present invention has a pair of electrodes and organic layers including a light-emitting layer between the pair of the electrodes. At least one of the organic layers, and preferably the light-emitting layer comprises the hexacoordinated organoantimony complex.

### BACKGROUND OF THE INVENTION

### Field of Invention

The present invention relates to an organic light-emitting diode including a light-emitting layer comprising a hexacoordinated organoantimony complex.

### Description of the Related Art

When a voltage is applied between a pair of electrodes constituting an organic light-emitting diode (OLED), holes from an anode and electrons from a cathode are injected into a light-emitting layer including organic compounds as luminescence materials, and the injected electrons and holes are recombined and form exciton in the luminous organic compounds. Consequently, the excited organic compounds emit luminescence. In other words, because of being a self-luminous element, the OLED is superior in brightness and visibility to the liquid crystal element, and gives us a clear image. The OLED is expected as a light-emitting element which has high luminous efficiency, high resolution, low power consumption, long lifetime and flat design, taking advantage of the self-luminous element.

In order to improve the performance of the OLED, an attempt has been carried out to make a light-emitting layer into a host/dopant layer where the host is doped with a luminescence material as a dopant. The light-emitting layer made in this way can prevent luminescent excitons from quenching, when for example included in a three-layer structure having a hole transport layer, a light-emitting layer and an electron transport layer. The following are the details: The HOMO energy level of the host is made to match that of the hole transport material, and the LUMO of the hole transport layer is raised enough to transfer holes to the light-emitting layer completely. And the LUMO energy levels of the host and the electron transport layer are also aligned with their interface. Meanwhile, the HOMO of the electron transport layer is made deep enough to confine the charge, and moreover, the energies of triplet excitons of the hole transport material and the electron transport material are raised much higher than the triplet level of the luminescent material. The luminescent excitons are thus prevented from quenching.

In the light-emitting layer, excitons are effectively generated from the charge injected into the host. The energy of the excitons generated is transferred to the dopant, and thereby the dopant provides high-efficiency luminance.

To meet the requirement of energy levels of such materials, a search has been carried out for materials having a variety of building blocks. For example, carbazole compounds, such as 4,4′-bis(9-carbazolyl)biphenyl and 1,3-bis(9-carbazolyl)benzene are well-known as a host.

Attention has been focused on hetero elements in the lower region of the periodic table. Research have been conducted on designing molecules to find characteristics beyond intrinsic properties in these hetero elements and on synthesizing compounds containing hetero elements in the lower region of the periodic table, and the research to clarify the physical properties and function are also carried out. For example, an intramolecularly coordinated neutral hexacoordinated organoantimony complex is reported as LSb(Xy1)C₆H₄(o-Y) [L represents a tridentate ligand, Xy1 represents 3,5-dimethylphenyl group, and Y represents methoxymethyl group, dimethylaminomethyl group or 2-pyridyl group (Heteroatom Chemistry (2011), 22 (3-4), 553-561). As to the foregoing hexacoordinated organoantimony complex when Y is methoxymethyl group or dimethylaminomethyl group, the measurement of variable temperature NMR spectra shows that stereomutation occurs in dissociating the bond between antimony and the donor (nitrogen or oxygen) and thereby causes the antimony-carbon bond to rotate. However, OLEDs using a hexacoordinated organoantimony complex for luminescent material etc, have not yet been reported.

### BRIEF SUMMARY OF THE INVENTION

An object of the present invention is to provide not only a novel hexacoordinated organoantimony complex, but also a blue light-emitting OLED comprising the hexacoordinated organoantimony complex.

The hexacoordinated organoantimony complex of the present invention has an intramolecular ligand so as to form an antimony-centered hexacoordinated structure.

The hexacoordinated organoantimony complex of the present invention has an intramolecular ligand so as to form an antimony-centered hexacoordinated structure, wherein carbons and antimony form at least one carbon-antimony bond in the intramolecular ligand.

The hexacoordinated organoantimony complex of the present invention has an intramolecular ligand so as to form an antimony-centered hexacoordinated structure, wherein carbons and antimony form one to three carbon-antimony bonds in the intramolecular ligand.

The hexacoordinated organoantimony complex of the present invention has a moiety represented by the following general formula (1).

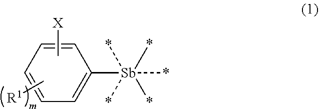

In the general formula (1), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, X is a functional group of a monovalent 5- to 7-membered ring, and two neighboring atoms in the 5- to 7-membered ring may combine with two carbon atoms of phenyl group to form a condensed ring. In the general formula (1), asterisk represents a binding site and Sb is hexacoordinated.

The hexacoordinated organoantimony complex of the present invention has a moiety represented by the following general formula (2).

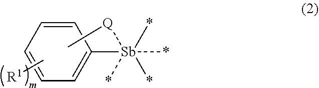

In the general formula (2), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, Q is a monovalent or divalent 5- to 7-membered ring functional group having at least one hetero atom, or a hydrogen atom, and atoms constituting Q may combine directly with Sb. In the general formula (2), asterisk represents the binding site and Sb is hexacoordinated.

The hexacoordinated organoantimony complex of the present invention has a moiety represented by the following general formula (3).

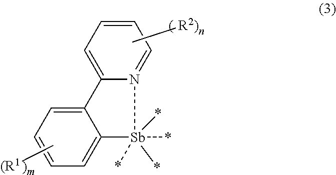

In the general formula (3), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, R² is hydrogen or deuterium, and n is an integer of 1 to 4. In the general formula (3), asterisk represents the binding site and Sb is hexacoordinated.

The hexacoordinated organoantimony complex of the present invention has a skeleton represented by the following general formula (4).

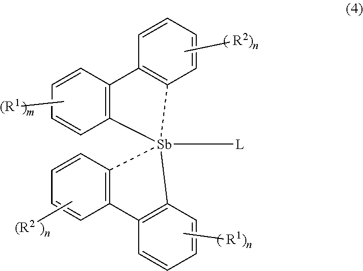

In the general formula (4), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, R² is hydrogen or deuterium, n is an integer of 1 to 4, and L is a bidentate ligand coordinated with Sb.

The hexacoordinated organoantimony complex of the present invention has a skeleton represented by the following general formula (5).

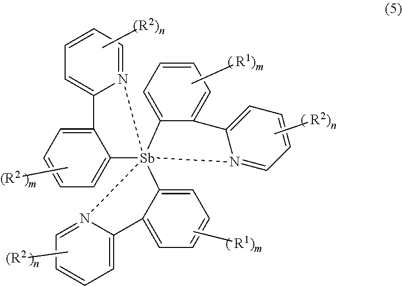

In the general formula (5), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, R² is hydrogen or deuterium, and n is an integer of 1 to 4.

The organic light-emitting-diode of the present invention has a pair of electrodes and the organic layers including a light-emitting layer between the pair of the electrodes, wherein at least one of the organic layers comprises the hexacoordinated organoantimony complex.

Preferably, the light-emitting layer comprises the hexacoordinated organoantimony complex.

The hexacoordinated organoantimony complex of the present invention emits pure blue light required for full color television, so that it is suitably used as blue light-emitting materials.

The hexacoordinated organoantimony complex of the present invention is chemically and thermally stable because of the stable structure of the bidentate ligand, which results in preventing decomposition or denaturation, even if the hexacoordinated organoantimony complex is exposed to vapor deposition at 300 to 400° C. under vacuum in manufacturing the OLED.

### BRIEF DESCRIPTION OF THE DRAWING

FIG. 1 represents the structure of the organic light-emitting diode of the present invention.

### DESCRIPTION OF THE PREFERRED EMBODIMENTS

The hexacoordinated organoantimony complex of the present invention and the OLED will be described in detail.

### [Hexacoordinated Organoantimony Complex]

The hexacoordinated organoantimony complex of the present invention has an intramolecular ligand so as to form an antimony-centered hexacoordinated structure. To be specific, the hexacoordinated organoantimony complex has an intramolecular ligand so as to have an antimony-centered octahedral structure, wherein carbons and antimony form at least one carbon-antimony bond in the intramolecular ligand.

The intramolecular ligand is an organic compound bonded to antimony. The intramolecular ligand includes various ligands, such as a monodentate ligand and a bidentate ligand. These ligands are bonded to antimony to form a hexacoordinated structure in the hexacoordinated organoantimony complex of the present invention. In general, the ligand refers to a group having an unshared electron pair to coordinate with metals. However, the present specification includes an embodiment in which the intramolecular ligand is bonded to antimony not only through a coordinate bond, but also through an ionic bond or covalent bond.

The monodentate ligand includes ammine, halide ion and cyanide ion.

The bidentate ligand includes a group with a structure, such as acetylacetone (acac), 2-phenylpyridine, 2-picolinic acid, 2-(2,4-difluorophenyl)pyridine, trifluoroacetylacetone, 2-(4-cyanophenyl)pyridine, 1,10-phenanthroline, 2-phenyl-2H-indazole, 2-phenylbenzoxazole, 4-(triphenylsilyl)phenylpyridine, benzoquinoline, 2-(4-triphenylsilylphenyl)pyridine and deuterated 2-phenylpyridine.

Polydentate ligands generally tend to form more stable complexes than monodentate ligands when they have equal coordinate ability. When a bidentate ligand is bonded to antimony, the hexacoordinated organoantimony complex of the present invention becomes chemically and thermally stable, which is desirable.

In the hexacoordinated organoantimony complex, carbons format least one bond with antimony. The carbon-antimony bond is a sigma bond (σ bond) in the intramolecular ligand. A σ bond is one of covalent bonds, being a strong bond. The hexacoordinated organoantimony complex is chemically and thermally stable, because carbons and antimony form a strong bond in the intramolecular ligand.

In the hexacoordinated organoantimony complex of the present invention, carbons form one to three carbon-antimony bonds with antimony in the intramolecular ligand, which gets desirable in terms of stability. However, when the number of covalent bonds is four or more, the hexacoordinated organoantimony complex becomes more unstable in comparison with the case of one to three covalent bonds, because the configuration of the intramolecular ligand surrounding antimony is distorted.

The hexacoordinated organoantimony complex of the present invention has a moiety represented by the general formula (1).

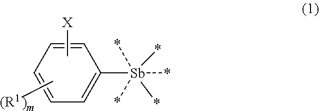

In the general formula (1), R¹ is hydrogen, deuterium, an alkyl group having 1 to 6 carbon atoms, an alkoxy group having 1 to 6 carbon atoms, an aryl group having 5 to 30 core atoms, fluorine, cyano group and triphenylsilyl group, and m is an integer of 1 to 4, specifically an integer of 1 to 2.

The alkyl group having 1 to 6 carbon atoms includes methyl group, ethyl group, propyl group, isopropyl group, n-butyl group, isobutyl group, s-butyl group, t-butyl group, n-pentyl group, neopentyl group, isopentyl group, s-pentyl group, 3-pentyl group, t-pentyl group, n-hexyl group, 2-methylpentyl group, 3-methylpentyl group, 2,2-dimethylbutyl group and 2,3-dimethylbutyl group.

The alkoxy group having 1 to 6 carbon atoms includes methoxy group, ethoxy group, propoxy group, isopropoxy group, n-butoxy group, isobutoxy group, s-butoxy group, t-butoxy group, n-pentoxy group, neopentoxy group, isopentoxy group, s-pentoxy group, 3-pentoxy group, t-pentoxy group, n-hexoxy group, 2-methylpentoxy group, 3-methylpentoxy group, 2,2-dimethylbutoxy group and 2,3-dimethylbutoxy group.

The aryl group having 5 to 30 core atoms includes groups with moieties, such as phenyl, naphthyl, terphenyl, phenanthryl, anthryl, pyrenyl, fluoranthenyl, chrysenyl, triphenylenyl, stilbenyl, triptycenyl, perylenyl, pyridyl, pyrimidinyl, triazinyl, pyrrolyl, indolyl, carbazolyl, furanyl, benzofuranyl, dibenzofuranyl, thiophenyl, benzothiophenyl, dibenzothiophenyl, oxazolyl and oxadiazolyl.

X is a monovalent 5- to 7-membered ring. The monovalent 5- to 7-membered ring includes phenyl, pyridyl, oxetanyl, pyrrolyl, pyrrolidinyl, imidazolyl, pyrazolyl, triazinyl, triazolyl, furanyl, tetrahydrofuranyl, oxazolyl, isoxazolyl, oxadiazolyl, thiophenyl, dioxanyl, pyranyl, pyrimidinyl, piperazinyl, pyranyl, oxazinyl, morpholinyl and oxepanyl.

To be specific, the hexacoordinated organoantimony complex has a moiety represented by the general formula (2). In the general formula (2), Q is a monovalent or a divalent 5- to 7-membered ring having at least one hetero atom, or a hydrogen atom.

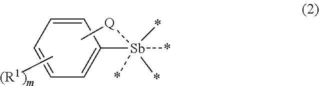

A specific example of the monovalent or the divalent 5- to 7-membered ring having at least one hetero atom includes a monovalent or a divalent substituent with a moiety, such as pyridine, deuterated pyridine, oxetane, pyrrole, pyrrolidine, imidazole, pyrazole, triazine, triazole, furan, tetrahydrofuran, oxazoline, isooxazoline, oxadiazoline, thiophene, dioxane, pyran, pyrimidine, piperazine, pyran, oxazine, morpholine and oxepane. Among these, the substituents having a moiety, such as pyridine, deuterated pyridine, imidazole and oxazoline are preferable.

Two neighboring atoms in Q may combine with two carbon atoms of phenyl group and forma condensed ring, such as indazole, benzoquinoline and benzoxazole.

When Q is a divalent 5- to 7-membered ring, atoms constituting Q combine directly with Sb. A dotted line linking Q and Sb indicates that Q can combine with antimony. When Q combines with antimony, Q and phenyl group form a bidentate ligand.

The hexacoordinated organoantimony complex of the present invention has a moiety represented by the general formula (3).

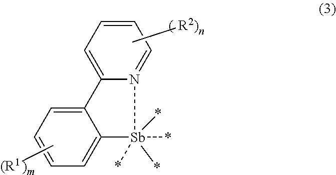

In the general formula (3), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, and m is an integer of 1 to 4, specifically an integer of 1 to 2. R² is hydrogen or deuterium, and n is an integer of 1 to 4, specifically an integer of 1 to 2. In the general formula (3), a dotted line linking N and antimony indicates that Q and antimony form a coordinate bond or covalent bond.

The hexacoordinated organoantimony complex of the present invention has a skeleton represented by the following general formula (4).

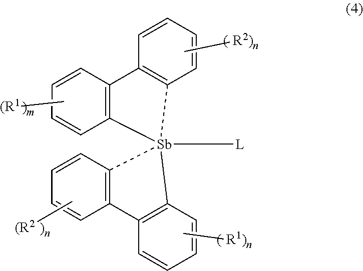

In the general formula (4), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, specifically an integer of 1 to 2. R² is hydrogen or deuterium and n is an integer of 1 to 4, specifically an integer of 1 to 2.

L is a bidentate ligand coordinated with Sb. Specific examples include 2-phenylpyridine, acetylacetone, trifluoroacetylacetone, 2-picolinic acid and 9,10-phenanthroline.

The hexacoordinated organoantimony complex of the present invention has a skeleton represented by the general formula (5).

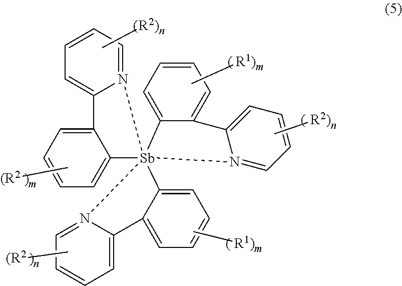

In the general formula (5), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, and m is an integer of 1 to 4, specifically an integer of 1 to 2.

Specific examples of the alkyl group having 1 to 6 carbon atoms, the alkoxy group having 1 to 6 carbon atoms, and the aryl group having 5 to 30 core atoms, which represent R¹ in the general formulae (2) to (5), are the same as those of the general formula (1).

It is particularly preferable that the hexacoordinated organoantimony complex of the present invention have the following structural formula.

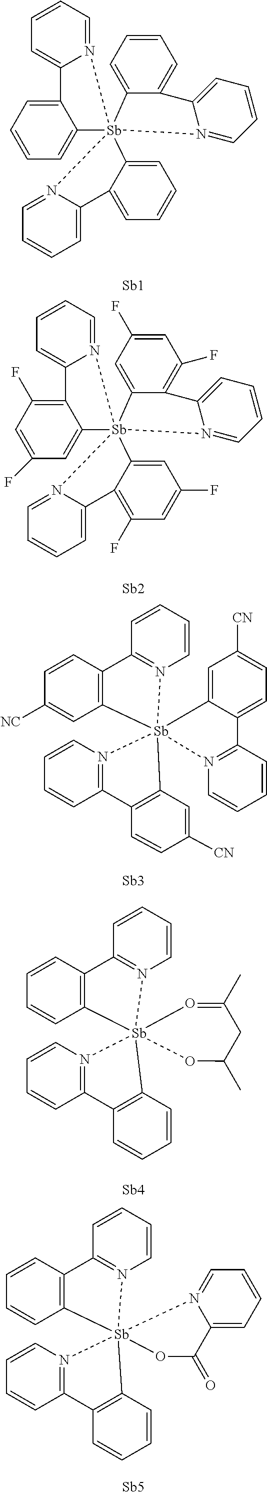

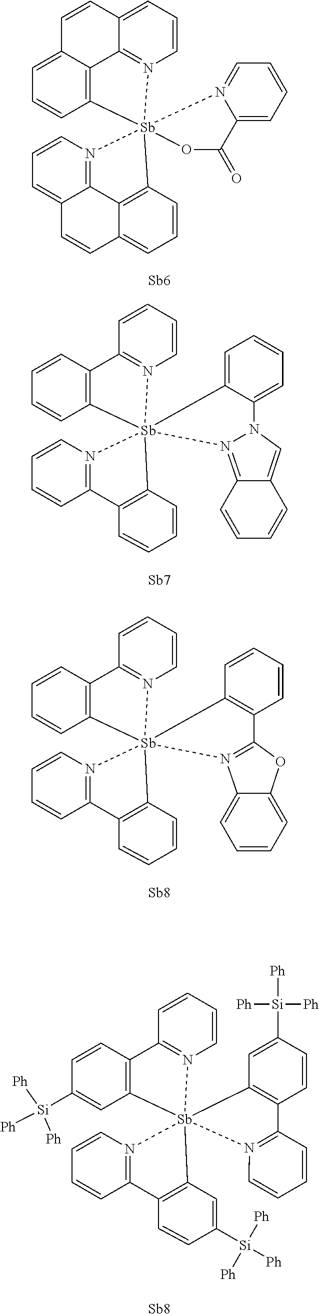

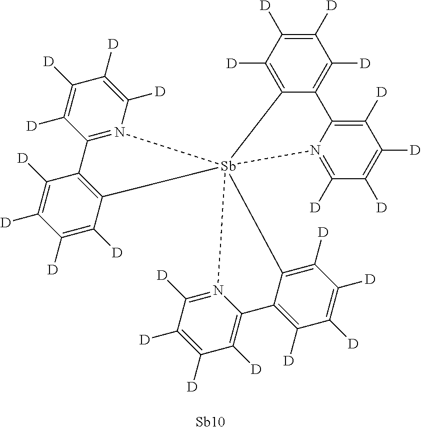

The hexacoordinated organoantimony complex of the present invention can be synthesized by various known methods. A method of synthesizing Sb1 is shown as one example.

n-Butyl lithium is added at −70° C. to a dry diethyl ether solution to which 2-(2-iodophenyl)pyridine is added, and the solution is stirred until a yellow suspension of 2-(2-lithiophenyl)pyridine is obtained. Next, to a dry diethyl ether solution to which antimony chloride is added, the yellow suspension of 2-(2-lithiophenyl)pyridine is added and the mixture is stirred at −70° C. The obtained reaction mixture is purified and Sb is obtained in good yield.

The hexacoordinated organoantimony complex of the present invention has the stable structure in which the bidentate ligand is coordinated with the antimony in the center, which is confirmed by ¹H- and ¹³C-NMR, LC-MS, elemental analysis, etc.

The hexacoordinated organoantimony complex is likely to work as a blue light-emitting material when used as an OLED material, because of its blue light-emitting characteristics. The hexacoordinated organoantimony complex is thermally too stable to decompose or denature even under heated vacuum evaporation at 300 to 400° C. in order to produce the OLED.

### [Organic Light-Emitting Diode]

The OLED of the present invention has a pair of electrodes consisting of anode 2 and cathode 7, organic layers including a light-emitting layer 4 between the pair of electrodes. At least one layer of the organic layers includes the hexacoordinated organoantimony complex. The organic layers include the light-emitting layer 4, a hole blocking layer and an electron transport layer 5. Among these layers, the light-emitting layer 4 is preferably composed of the hexacoordinated organoantimony complex.

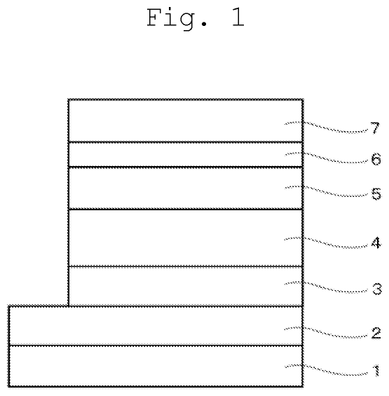

Typically, the OLED has such a layered structure as to deposit an anode 2 (e.g., indium tin oxide (ITO)) on the substrate 1 and then to deposit a hole injection layer, a hole transport layer 3, a light-emitting layer 4, a hole blocking layer, an electron transport layer 5, an electron injection layer 6 and a cathode 7 on the anode 2 in this order. An electron blocking layer may be inserted between the hole transport layer 3 and the light-emitting layer 4. Some layers may be omitted in the multi-layer structure. The electron injection layer 6 may be an electron injection and transport layer which also functions as the electron transport layer 5. FIG. 1 is an embodiment of the present invention, and represents the OLED in which 4,4′-bis[phenyl(1-naphthyl)amino]biphenyl (NPB) with a thickness of 40 nm as the hole transport layer 3, the hexacoordinated organoantimony complex of the present invention with a thickness of 40 nm as the light-emitting layer 4, 2,9-di(2-naphthyl)-4,7-diphenyl-1,10-phenanthroline (ET1) with a thickness of 30 nm as the electron transport layer 5, lithium fluoride with a thickness of 1 nm as the electron injection layer 6, and aluminum with a thickness of 100 nm as the cathode 7 are layered on the ITO transparent electrode 2.

Transparent and smooth materials having a total light transmittance of at least 70% or more are used for the substrate 1. To be more concrete, the substrate includes flexible transparent substrate, such as glass substrate having a thickness of several micrometers or special transparent plastic.

The anode 2 has a function to inject holes into the hole injection layer, the hole transport layer 3 and the light-emitting layer 4. In general, metal oxides, metals, alloys, and conductive materials having a work function of 4.5 eV or more are used as the anode 2 materials, while from the viewpoint of transmitting the emitted light, the materials having a total light transmittance of 80% or more are usually preferable. A specific example includes transparent conductive ceramics such as ITO and zinc oxide (ZnO), transparent conductive materials such as poly(3,4-ethylenedioxythiophene)/poly(4-styrene sulfonic acid) (PEDOT-PSS) and polyaniline. The anode 2 usually has a thickness of 5 to 500 nm and preferably 10 to 200 nm.

The anode 2 is formed by vapor deposition method, electron beam method, sputtering method, chemical reaction method, and coating method.

The cathode 7 has a function to inject electrons into the electron injection layer 6, the electron transport layer 5, and the light-emitting layer 4. In general, metals and alloys having a work function of approximately 4 eV or less are appropriate for the cathode 7 materials. The metal used as the cathode 7 includes aluminum, lithium, sodium, potassium, calcium and magnesium. An example of the cathode made of an alloy is an electrode of an alloy of the foregoing low-work function metal and metals such as aluminum and silver, or a layer-structured electrode composed of the low-work function metal and metals such as aluminum and silver. The cathode 9 usually has a thickness of 10 to 200 nm.

The cathode 7 is formed by vapor deposition method, electron beam method, sputtering method, chemical reaction method, and coating method.

The hole injection layer is introduced to improve the luminous efficiency. To supply the current at low voltage, the hole injection layer should be 1 to 20 nm-thick, which means thin enough not to cause pinholes, and yet uniform. The hole injection material includes triphenylamine-containing polymer:(4-isopropyl-4′-methyldiphenyliodonium tetrakis(pentafluorophenyl)borate (KLHIP:PPBI), triphenylamine-containing polyether ketone (TPAPEK), hexaazatriphenylenecarbonitrile (HATCN), poly(3,4-ethylenedioxythiophene) (PEDOT:PSS), phenylamine type, starburst amine type, poly(ether ketones) (PEK) and polyaniline.

The hole transport layer 3 which is placed between the anode 2 and the light-emitting layer 4, works for transporting holes from the anode 2 to the light-emitting layer 4 efficiently. The material having a small ionization potential, that is to say, the material which easily excites electrons from the HOMO and generates holes is used as the hole transport material. Specific examples include 4,4′-bis[phenyl(l-naphthyl)amino]biphenyl (NPB), hexaphenylbenzene derivative (4DBTHPB), poly(9,9-dioctylfluorene-alt-N-(4-butylphenyl)diphenylamine) (TFB), 4,4′-cyclohexylidenebis[N,N-bis(4-methylphenyl)benzenamine] (TAPC), N,N′-diphenyl-N,N′-di(m-tolyl)benzidine (TPD), 4,4′,4″-tri-9-carbazolyltriphenylamine (TCTA) and 4,4′,4″-tris[phenyl(m-tolyl)amino]triphenylamine.

The light-emitting layer 4 may be the one made of only luminescent materials. The luminescent materials may be used as a dopant in the light-emitting layer where the dopant and a host are comprised. Among such luminescent materials, not only the hexacoordinated organoantimony complex of the present invention, but also distyrylarylene derivatives, oxadiazole derivatives, polyvinylcarbazole derivatives, poly(p-phenylene) derivatives and polyfluorene derivatives are exemplified by blue light-emitting materials.

Dopants used for the light-emitting layer 4 made of the dopant and the host include perylene derivatives, coumarin derivatives, rubrene derivatives, quinacridone derivatives, squarylium derivatives, porphyrin derivatives, styryl type pigments, tetracene derivatives, pyrazolone derivatives, decacyclene and phenoxazone.

There is no particular limitation on the host, provided that the host minimizes charge injection barrier from the hole transport layer 3 and the electron transport layer 5, confines the charge within the light-emitting layer 4, and prevents the luminescence excitons from quenching. For example, 9,9′-diphenyl-9H,9′H-3,3′-dicarbazole (BCzPh), bis[2-(diphenylphosphino)phenyl] ether oxide (DPEPO), 3,6-bis(diphenylphosphoryl)-9-phenylcarbazole (PO9), 4,4′-bis(N-carbazolyl)-1,1′-biphenyl (CBP), 3,3′-bis(N-carbazolyl)-1,1′-biphenyl (mCBP), tris(4-carbazoyl-9-ylphenyl)amine (TCTA), 2,8-bis(diphenylphosphoryl)dibenzothiophene (PPT), adamantane-anthracene (Ad-Ant), rubrene, 2,2′-bi(9,10-diphenylanthracene) (TPBA) and 1,4-di(1,10-phenanthrolin-2-yl)benzene (DPB) are given.

The amount of the luminescent material is approximately 0.1 to 10 wt % based on the total amount of the luminescent material and the host.

The hole blocking layer has a role in enhancing the probability of recombining electrons with holes in the light-emitting layer 4 while transporting the electrons with the holes being kept away from the electron transport layer 5. The hole blocking material includes 2-(3′-(dibenzo[b,d]thiophen-4-yl)-[1,1′-biphenyl]-3-yl)-4,6-diphenyl-1,3,5-triazine (DBT-TRZ), phenanthroline derivatives such as bathocuproine (BCP), metal complexes of quinolinol derivatives such as aluminum(III) bis(2-methyl-8-quinolinato)-4-phenylphenolate (BAlq), various rare earth complexes, oxazole derivatives, triazole derivatives, triazine derivatives, pyrimidine derivatives, oxadiazole derivatives, and benzoxazole derivatives. These materials can be also used as the materials for the electron transport layer 5.

The electron transport layer 5 which is placed between the cathode 7 and the light-emitting layer 4, has a role in transporting electrons from the cathode to the light-emitting layer efficiently. The electron transport materials which have high electron affinity, in other words, the materials which make the energy level of the LUMO lower and make the electrons be easily excited are available. Examples include 2,9-di(2-naphthyl)-4,7-diphenyl-1,10-phenanthroline (ET1), 3,3″,5,5′-tetra(3-pyridyl)-1,1′; 3′,1″-terphenyl (B3PyPB), 4,6-bis(3,5-di(pyridin-3-yl)phenyl)-2-methylpyrimidine (B3PyMPM), 2-(4-biphenylyl)-5-(p-t-butylphenyl)-1,3,4-oxadiazole (tBu-PBD), 1,3-bis[5-(4-t-butylphenyl)-2-[1,3,4]oxadiazolyl]benzene (OXD-7), 3-(biphenyl-4-yl)-5-(4-t-butylphenyl)-4-phenyl-4H-1,2,4-tri azole (TAZ), bathocuproine (BCP), and 1,3,5-tris(1-phenyl-1H-benzimidazol-2-yl)benzene (TPBi).

The electron injection layer 6 which is in contact with the cathode has a role in transporting electrons. The electron injection material includes lithium fluoride (LiF), 8-hydroxyquinolinolato-lithium (Liq), and lithium 2-(2′,2″-bipyridin-6′-yl)phenolate (Libpp).

The hole injection layer, the hole transport layer 3, the light-emitting layer 4, the electron transport layer 5 and the electron injection layer 6, which are formed on the substrate 1, are film-formed by vacuum deposition methods or coating methods.

The vacuum deposition methods include resistance heating evaporation, electronic beam evaporation, sputtering method, and molecular stacking method. In a case where the vacuum deposition method is applied, a vapor deposition substance is usually heated from 300 to 400° C. in an atmosphere of a reduced pressure of 10⁻³ Pa or less.

In a case where the coating method is applied, materials for each layer are dissolved in chloroform, methylene chloride, dichloroethane, tetrahydrofuran, toluene, xylene, acetone, methyl ethyl ketone, ethyl acetate, butyl acetate, ethyl cellosolve acetate, water and so on, and then each layer is formed by a known coating method. The coating methods include bar coating method, capillary coating method, slit coating method, ink-jet coating method, spray coat method, nozzle coat method, and printing method. Each layer may be formed by the same coating method, or optimal coating method may be applied severally according to the type of inks.

The thickness of each organic layer between the anode 2 and the cathode 7 is usually 1 to 100 nm and preferably 1 to 50 nm, although some differences exist depending on the resistance values and the charge mobility of constituent materials.

Besides the single wafer process, the OLED of the present invention may be manufactured by the roll-to-roll process, for example.

### EXAMPLES

Hereinafter, the present invention will be described in detail with reference to examples, but the present invention is not restricted thereto.

### [Example 1] Synthesis of Sb1

To a 50 mL reactor was added 2.16 g (7.68 mmol) of 2-(2-iodophenyl)pyridine, and after the atmosphere of the reactor was replaced with argon, 25 mL of dry diethyl ether was poured into the reactor. To the reactor cooled to −70° C., 5.4 mL (8.64 mmol) of n-butyl lithium solution (1.60 M hexane solution) was dripped, and the solution was stirred for 3 hours while cooling and a yellow suspension of 2-(2-lithiophenyl)pyridine was obtained. To a 100 mL reactor, 0.540 g (2.37 mmol) of antimony trichloride was added in an argon atmosphere and was followed by addition of 40 mL of dry diethyl ether. After the reactor was cooled to −70° C., the yellow suspension of 2-(2-lithiophenyl)pyridine prepared beforehand was slowly dripped into the solution of antimony trichloride. The solution was stirred at −70° C. for 2 hours, then returned to room temperature, and further stirred overnight. After filtration, the reaction mixture was washed with diethyl ether, and the residue was dissolved into toluene. The solution was distilled to remove the toluene to give 0.82 g of Sb1 in a yield of 59%.

m.p. 208° C.

¹H NMR (500 MHz, CDCl₃, 25° C.) δ 7.01 (ddd, J=7.4, 4.8, 1.1 Hz, 1H), 7.11 (dt, J=7.4, 1.1 Hz, 1H), 7.34 (dt, J=7.4, 1.1 Hz, 1H), 7.53 (dd, J=7.4, 1.1 Hz, 1H), 7.59 (dt, J=7.4, 1.8 Hz, 1H), 7.65 (d, J=8.0 Hz, 1H), 7.78 (d, J=7.7 Hz, 1H), 8.26 (d, J=4.8 Hz, 1H). ¹³C NMR (126 MHz, CDCl₃, 25° C.) δ 121.7, 121.7, 127.3, 127.5, 128.6, 136.3, 138.6, 144.5, 147.8, 148.4, 159.1.

MS (APCI, pos) m/z 582 ([M-1]⁺), 429 ([M-(ppy)]⁺), 275 ([M-2 (ppy)]⁺).

Elemental analysis calcd (%) for C₃₃H₂₄N₃Sb: C, 67.83; H, 4.14; N, 7.19; found: C, 67.64; H, 4.10; N, 7.17.

### [Example 2] Manufacturing and Evaluation of the OLED

A glass substrate of 26 mm×28 mm×0.7 mm (manufactured by Opto Science Inc.,), on which ITO was sputtered to a thickness of 180 nm and then polished to 150 nm, was used as a transparent support substrate. The transparent support substrate was fixed to a substrate holder of a commercially available deposition apparatus (manufactured by Showa Shinku Co., Ltd.). The deposition apparatus was equipped with a vapor deposition boat made of molybdenum containing 4,4′-bis[phenyl(l-naphthyl)amino]biphenyl (NPB), a vapor deposition boat made of molybdenum containing Sb1, a vapor deposition boat made of molybdenum containing 2,9-di(2-naphthyl)-4,7-diphenyl-1,10-phenanthroline (ET1), a vapor deposition boat made of molybdenum containing lithium fluoride, and a vapor deposition boat made of tungsten containing aluminum.

Each layer was successively formed on the ITO film of the transparent support substrate as described below. The inside pressure of a vacuum chamber was reduced to 5×10⁻⁴ Pa, and first of all, the vapor deposition boat containing NPB was heated, so that NPB could vaporize and form the hole transport layer with a thickness of 40 nm. Next, the vapor deposition boat containing Sb1 was heated, so that Sb1 could vaporize and form the light-emitting layer with a thickness of 40 nm.

The vapor deposition boat containing ET1 was heated, so that ET1 could vaporize and form the electron transport layer with a thickness of 30 nm.

The vapor deposition rate of each layer was 1 to 2 nm/s.

Then the vapor deposition boat containing LiF was heated so that LiF was vapor deposited to a thickness of 1 nm at a vapor deposition rate of 0.01 to 0.1 nm/s. The vapor deposition boat containing aluminum was heated, and the cathode was formed with a thickness of 100 nm at a vapor deposition rate of 0.01 to 2 nm/s, which resulted in the OLED.

When the direct current was applied to the OLED with an ITO electrode as an anode and a LiF/aluminum electrode as a cathode, blue light emission was observed.

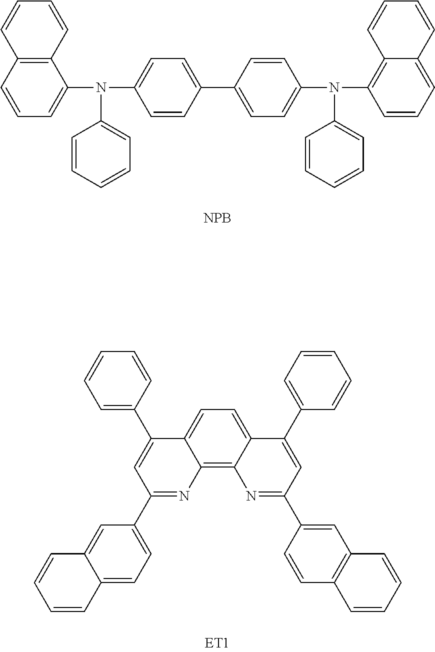 [SMILES: c1ccc(N(c2ccc(-c3ccc(N(c4ccccc4)c4cccc5ccccc45)cc3)cc2)c2cccc3ccccc23)cc1 ; "NPB" ; c1ccc(-c2cc(-c3ccc4ccccc4c3)nc3c2ccc2c(-c4ccccc4)cc(-c4ccc5ccccc5c4)nc23)cc1]

The OLED including the luminescent material of the hexacoordinated organoantimony complex of the present invention can give pure blue light emission required for full color television.

1. A hexacoordinated organoantimony complex having an intramolecular ligand so as to form an antimony-centered hexacoordinated structure.

2. A hexacoordinated organoantimony complex having an intramolecular ligand so as to form an antimony-centered hexacoordinated structure, wherein carbons and antimony form at least one carbon-antimony bond in the intramolecular ligand.

3. A hexacoordinated organoantimony complex having an intramolecular ligand so as to form an antimony-centered hexacoordinated structure, wherein carbons and antimony form one to three carbon-antimony bonds in the intramolecular ligand.

4. A hexacoordinated organoantimony complex having a moiety represented by the following general formula (1): 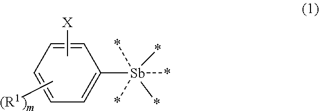
in the general formula (1), R¹ is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, X is a functional group of a monovalent 5- to 7-membered ring, and two neighboring atoms in the 5- to 7-membered ring may combine with two carbon atoms of phenyl group to form a condensed ring.

5. A hexacoordinated organoantimony complex having a moiety represented by the following general formula (2): 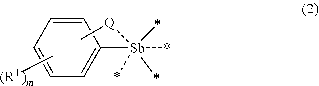
in the general formula (2), R1 is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, Q is a functional group of a 5- to 7-membered ring having at least one hetero atom, or a hydrogen atom, and Q may combine directly with Sb.

6. A hexacoordinated organoantimony complex having a moiety represented by the following general formula (3): 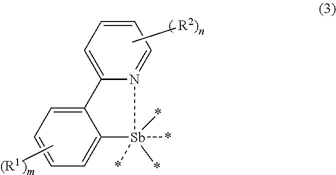
in the general formula (3), R1 is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, R2 is hydrogen or deuterium, and n is an integer of 1 to 4.

7. A hexacoordinated organoantimony complex having a skeleton represented by the following general formula (4): 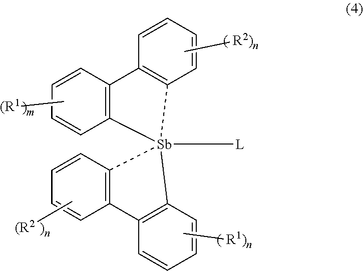
in the general formula (4), R1 is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, R2 is hydrogen or deuterium, n is an integer of 1 to 4, and L is a bidentate ligand coordinated with Sb.

8. A hexacoordinated organoantimony complex having a skeleton represented by the following general formula (5): 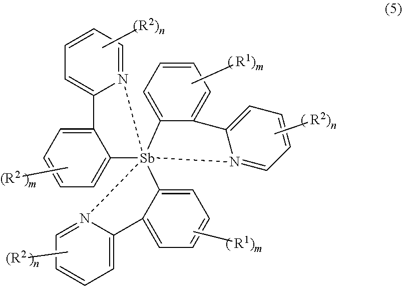
in the general formula (5), R1 is hydrogen, deuterium, an alkyl group having 1 to 6 carbon atoms, an alkoxy group having 1 to 6 carbon atoms, an aryl group having 5 to 30 core atoms, fluorine, cyano group or triphenylsilyl group, m is an integer of 1 to 4, R2 is hydrogen or deuterium, and n is an integer of 1 to 4.

9. An organic light-emitting diode having a pair of electrodes and organic layers including a light-emitting layer between the pair of the electrodes, wherein at least one of the organic layers comprises the hexacoordinated organoantimony complex according to claim 1.

10. An organic light-emitting diode having a pair of electrodes and organic layers including a light-emitting layer between the pair of the electrodes, wherein the light-emitting layer comprises the hexacoordinated organoantimony complex according to claim 1.
